(19) United States
(12) Patent Application Publication
(10) Pub. No.: US 2024/0014194 A1
(43) Pub. Date: Jan. 11, 2024

(54) DISPLAY DEVICE AND DISPLAY PANEL

(71) Applicant: Shenzhen China Star Optoelectronics Semiconductor Display Technology Co., Ltd., Shenzhen, Guangdong (CN)

(72) Inventor: Bei JIANG, Shenzhen, Guangdong (CN)

(21) Appl. No.: 17/295,333

(22) PCT Filed: Apr. 25, 2021
(86) PCT No.: PCT/CN2021/089697

§ 371 Date: May 19, 2021

(30) Foreign Application Priority Data
Apr. 13, 2021 (CN) 202110394073.3

(51) Int. Cl. H01L 25/16

(52) U.S. Cl. CPC H01L 25/167

(57) ABSTRACT

A display device and a display panel are provided. The display device includes a plurality of display panels configured to be spliced to form the display device. Each of the display panels includes a plurality of light-emitting units. In a splicing direction of the display panels, two adjacent light-emitting units in each display panel are separated by a first distance. The plurality of light-emitting units include a plurality of edge light-emitting units adjacent to another display panel along the splicing direction. The edge light-emitting units in one of the display panels are separated from the edge light-emitting units in another adjacent display panel by a second distance. A ratio of the second distance to the first distance in the splicing direction ranges from 0.8 to 1.2. This achieves seamless splicing between the plurality of display panels.

### FIELD OF DISCLOSURE

The present disclosure belongs to the technical field of electronic devices, and particularly relates to a display device and a display panel.

### BACKGROUND

In comparison with common liquid crystal displays (LCDs) and organic light-emitting diodes (OLEDs), micro-LED displays have better contrast, faster response speeds, higher brightness, and lower power consumption. The micro-LED display has a modular feature, and a plurality of display panels can be spliced into a large screen to meet user needs for space and aesthetics.

When a multi-screen display device formed by splicing two or more display panel modules displays an image, splicing regions between the display panel modules will cause discontinuities in the image, which will affect the user's visual perception.

### SUMMARY OF DISCLOSURE

Embodiments of the present disclosure provide a display device and a display panel, which can realize seamless splicing between a plurality of display panels.

In a first aspect, an embodiment of the present disclosure provides a display device, including:
a plurality of display panels configured to be spliced to form the display device.

Each of the display panels includes a plurality of light-emitting units. In a splicing direction of the display panels, two adjacent light-emitting units in each of the display panels are separated by a first distance. The plurality of light-emitting units include a plurality of edge light-emitting units adjacent to another display panel along the splicing direction. The edge light-emitting units in one of the display panels are separated from the edge light-emitting units in another adjacent display panel by a second distance. A ratio of the second distance to the first distance in the splicing direction ranges from 0.8 to 1.2.

In a second aspect, an embodiment of the present disclosure also provides a display panel, including: a substrate and a plurality of light-emitting units.

The substrate includes a first surface, a second surface opposite to the first surface, and a side surface connected between the first surface and the second surface.

The plurality of light-emitting units are disposed on the first surface of the substrate. In a preset direction, two adjacent light-emitting units are separated by a first distance, the light-emitting units arranged at an edge of the substrate are separated from the side surface by a third distance, and a ratio of the third distance to the first distance in the preset direction ranges from 0.4 to 0.6.

In the embodiment of the present disclosure, the display device includes the plurality of display panels. Each of the display panels includes the plurality of light-emitting units. In one display panel, two adjacent light-emitting units are separated by the first distance. The plurality of light-emitting units include the plurality of edge light-emitting units adjacent to another display panel along the splicing direction. The edge light-emitting units in one of the display panels are separated from the edge light-emitting units in another adjacent display panel by the second distance. The second distance is related to a distance between two adjacent display panels. If the second distance is too large, the distance between two adjacent display panels will be too far. Visually, there will be a gap between the two display panels, which will affect a continuity of an image. In the display device of the present disclosure, the ratio of the second distance to the first distance in the splicing direction ranges from 0.8 to 1.2. Thus, the gap between two adjacent display panels at a splicing point can be in a reasonable range. It prevents visually seeing the gap between two adjacent display panels. It ensures a display continuity of the display device spliced by the plurality of display panels, and realizes a seamless splicing of the plurality of display panels.

### BRIEF DESCRIPTION OF DRAWINGS

FIG. 1 is a first schematic diagram of a display device of an embodiment of the present disclosure.

FIG. 2 is a second schematic diagram of a display device of an embodiment of the present disclosure.

FIG. 3 is a top view of a display panel of an embodiment of the present disclosure.

FIG. 4 is a front view of the display panel of the embodiment of the present disclosure.

FIG. 5 is a left side view of the display panel of the embodiment of the present disclosure.

FIG. 6 is a partial enlarged view of an E portion shown in FIG. 4.

FIG. 7 is a flowchart of a manufacturing method of a display device of an embodiment of the present disclosure.

FIG. 8 is a first flowchart of a manufacturing method of a display panel of an embodiment of the present disclosure.

FIG. 9 is a second flowchart of a manufacturing method of a display panel of an embodiment of the present disclosure.

FIG. 10 shows schematic diagrams of manufacturing processes of the display panel of the embodiment of the present disclosure.

### DETAILED DESCRIPTION

Technical solutions in the embodiments of the present disclosure will be clearly and completely described below in conjunction with accompanying drawings in the embodiments of the present disclosure. Apparently, the described embodiments are only a part of the embodiments of the present disclosure, rather than all of the embodiments. Based on the embodiments in the present disclosure, all other embodiments obtained by those skilled in the art without creative efforts fall within a protection scope of the present disclosure.

An embodiment of the present disclosure provides a display device, including:
a plurality of display panels configured to be spliced to form the display device.

Each of the display panels includes a plurality of light-emitting units. In a splicing direction of the display panels, two adjacent light-emitting units in each display panel are separated by a first distance. The plurality of light-emitting units include a plurality of edge light-emitting units adjacent to another display panel along the splicing direction. The edge light-emitting units in one of the display panels are separated from the edge light-emitting units in another adjacent display panel by a second distance. A ratio of the second distance to the first distance in the splicing direction ranges from 0.8 to 1.2.

An embodiment of the present disclosure also provides a display panel, including: a substrate and a plurality of light-emitting units.

The substrate includes a first surface, a second surface opposite to the first surface, and a side surface connected between the first surface and the second surface.

The plurality of light-emitting units are disposed on the first surface of the substrate. In a preset direction, two adjacent light-emitting units are separated by a first distance, the light-emitting units arranged at an edge of the substrate are separated from the side surface by a third distance, and a ratio of the third distance to the first distance in the preset direction ranges from 0.4 to 0.6.

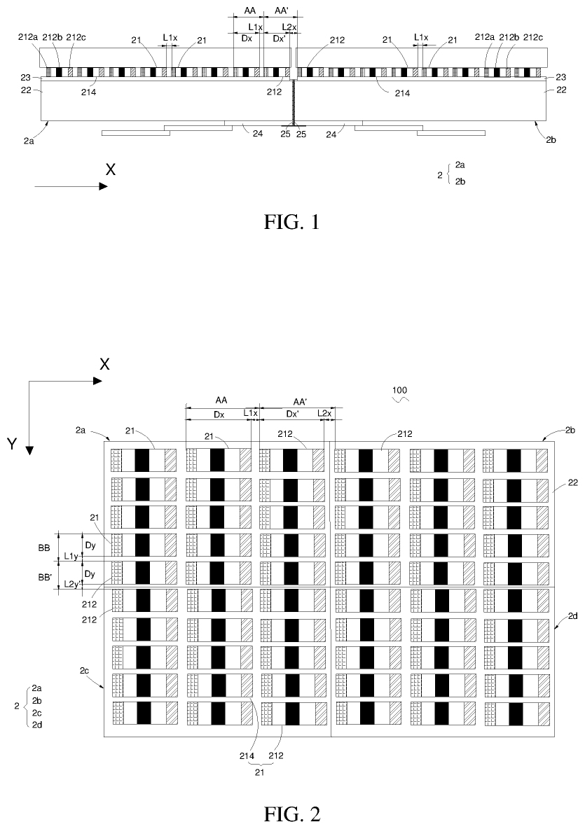

Please refer to FIG. 1, which is a first schematic diagram of a display device of an embodiment of the present disclosure. The embodiment of the present disclosure provides a display device 100. The display device 100 includes a plurality of display panels 2, and side surfaces of two adjacent display panels 2 are attached to each other for splicing to form the display device 100.

It should be noted that the display device 100 in the embodiment of the present disclosure is a micro-LED display. A micro-LED structure can be understood as a thin-film and miniaturized LED structure. A size of the micro-LED structure is only about 1-10 um. The micro-LED structure can include light-emitting sub-units of a plurality of colors. Red (R) light-emitting sub-units, green (G) light-emitting sub-units, and blue (B) light-emitting sub-units are formed in a thin film transistor (TFT) drive circuit according to certain rules through a mass transfer technology, to form a periodic array of light-emitting units. Each R light-emitting sub-unit, G light-emitting sub-unit, and B light-emitting sub-unit has an independent driving part, so that an individual control of light-emitting of each R light-emitting sub-unit, G light-emitting sub-unit, and B light-emitting sub-unit can be realized through the driving part. The micro-LED display has modular features. The display panels 2 can be understood as modules constituting the display device 100. The plurality of display panels 2 (such as a first display panel 2a and a second display panel 2b) are spliced to form the complete display device 100. The plurality of display panels 2 can be spliced into a large screen to meet different needs of users for space and aesthetics, thereby achieving higher flexibility. It can be understood that, in some embodiments, the micro-LED structure may also include other color light-emitting sub-units, such as white (W) light-emitting sub-units.

The display panel 2 may include a plurality of light-emitting units 21. A portion of the light-emitting units disposed at an edge of the display panel 2 and adjacent to an adjacent display panel 2 may be defined as edge light-emitting units 212. A portion of the light-emitting units disposed in a non-edge area in one display panel 2 can be defined as non-edge light-emitting units 214. For example, in FIG. 1, the first display panel 2a includes the edge light-emitting units 212 adjacent to the second display panel 2b. The first display panel 2a includes the non-edge light-emitting units 214 disposed in a non-edge area. The second display panel 2b also includes the edge light-emitting units 212 adjacent to the first display panel 2a. The second display panel 2b includes the non-edge light-emitting units 214 disposed in a non-edge area.

Please refer to FIG. 1, it can be understood that in a first splicing direction (X direction), two adjacent light-emitting units 21 are separated by a first distance L1x in the X direction. Two edge light-emitting unit 212 in the first display panel 2a and the second display panel 2b are separated by a second distance L2x in the X direction. In this embodiment, a ratio of the second distance to the first distance along a same splicing direction ranges from 0.8 to 1.2. Specifically, the ratio of the second distance L2x to the first distance L1x along the first splicing direction (X direction) ranges from 0.8 to 1.2. According to visual research, when the distance between two adjacent light-emitting units 21 is less than a certain threshold, and the first distance between any two adjacent light-emitting units 21 is within a certain range in the same splicing direction (first distance L1x in the X direction), an image that human eyes see has continuity. Therefore, in the same display panel 2, the first distance between any two adjacent light-emitting units 21 is less than the certain threshold and within the certain range, which can make the image on the same display panel 2 have continuity. The second distance (second distance L2x in the X direction) is related to a distance between two display panels 2. If the second distance is too large, there will be a gap in a splicing point of the display panels, which means that seamless splicing cannot be achieved, and there are obvious splicing traces. In the display device of the embodiment of the present disclosure, the ratio of the second distance to the first distance along the same splicing direction ranges from 0.8 to 1.2, so that the gap between two adjacent display panels at the splicing point can be made within a reasonable range, thereby preventing visually seeing a gap between two adjacent display panels. Also, the second distance is roughly equal to the first distance, so the continuity of a single display panel when displaying the image can be continued to the display device formed by splicing the plurality of display panels.

It should be noted that, referring to FIG. 2 for details, in order to facilitate splicing, display panels are generally formed in regular shapes. For example, the display panels can be formed in rectangular, square, or other regular shapes. There may be a plurality of splicing directions of the display panels in a display device. Please refer to FIG. 2, which is a second schematic diagram of a display device of an embodiment of the present disclosure. A display device 100 may include two splicing directions, such as a first splicing direction (X direction) and a second splicing direction (Y direction). The display device may include a plurality of display panels 2 (such as a first display panel 2a, a second display panel 2b, a third display panel 2c, and a fourth display panel 2d). The first display panel 2a and the second display panel 2b are spliced along the first splicing direction (X direction). The third display panel 2c and the fourth display panel 2d are spliced along the first splicing direction (X direction). The first display panel 2a and the third display panel 2c are spliced along the second splicing direction (Y direction). The second display panel 2b and the fourth display panel 2d are spliced along the second splicing direction (Y direction). In this embodiment, the first splicing direction (X direction) is perpendicular to the second splicing direction (Y direction). Alternatively, in other optional embodiments, the first splicing direction (X direction) may not be perpendicular to the second splicing direction (Y direction).

Please refer to FIG. 2, the first display panel 2a includes edge light-emitting units 212 adjacent to the second display panel 2b and the third display panel 2c. The second display panel 2b includes edge light-emitting units 212 adjacent to the first display panel 2a and the fourth display panel 2d. The third display panel 2c includes edge light-emitting units 212 adjacent to the first display panel 2a and the fourth display panel 2d. The fourth display panel 2d includes edge light-emitting units 212 adjacent to the second display panel 2b and the third display panel 2c. In the first splicing direction (X direction), two adjacent light-emitting units 21 are separated by a first distance L1x in the X direction. Two adjacent edge light-emitting units 212 in the first display panel 2a and the second display panel 2b are separated by a second distance L2x in the X direction. In the X direction, a ratio of the second distance L2x in the X direction to the first distance L1x in the X direction ranges from 0.8 to 1.2. For details, please refer to the foregoing embodiment, which will not be repeated here. Correspondingly, in the second splicing direction (Y direction), two adjacent light-emitting units 21 are separated by a first distance L1y in the Y direction. Two adjacent edge light-emitting units 212 are separated by a second distance L2y in the Y direction. It can be understood that along the second splicing direction (Y direction), a ratio of the second distance L2x in the Y direction to the first distance L1x in the Y direction ranges from 0.8 to 1.2.

It is understandable that there will be a certain error in actual manufacturing, and the second distance may be slightly larger or smaller than the first distance, which will not affect the visual continuity. Therefore, the ratio of second distance to first distance does not need to be strictly a specific value. The specific ratio should fall within the range of 0.8 to 1.2. Preferably, the ratio of the second distance to the first distance is 1.

It should be noted that in some other embodiments, the display device may also be spliced in only one direction, such as splicing in the first splicing direction (X direction) or the second splicing direction (Y direction). The X direction and the Y direction are perpendicular to each other. The X direction may be along a width direction of a display sub-unit. The Y direction may be along a length direction of the display sub-unit.

In the splicing directions of the display device 100, each light-emitting unit has a length. It should be noted that the length of each light-emitting unit is not necessarily the same in manufacturing. In order to better realize the seamless splicing of the display panels, the length of the light-emitting unit can also be taken into consideration. Specifically, in the first splicing direction (X direction), a sum of a length Dx of the light-emitting unit 21 and the first distance L1x is a fourth distance AA. A sum of a length Dx′ of the edge light-emitting unit 212 and the second distance L2x is a fifth distance AA′. If the fifth distance AA′ and the fourth distance AA range from 0.9 to 1.1, the display device has better continuity. Correspondingly, in the second splicing direction (Y direction), a sum of a length Dy of the light-emitting unit 21 and the first distance L1y is a sixth distance BB. A sum of a length Dy′ of the edge light-emitting unit 212 and the second distance L2y is a seventh distance BB′. If a ratio of the seventh distance BB′ to the sixth distance BB ranges from 0.9 to 1.1, the display device has better continuity. Preferably, the ratio of the fifth distance to the fourth distance is 1, and the ratio of the seventh distance to the sixth distance is 1.

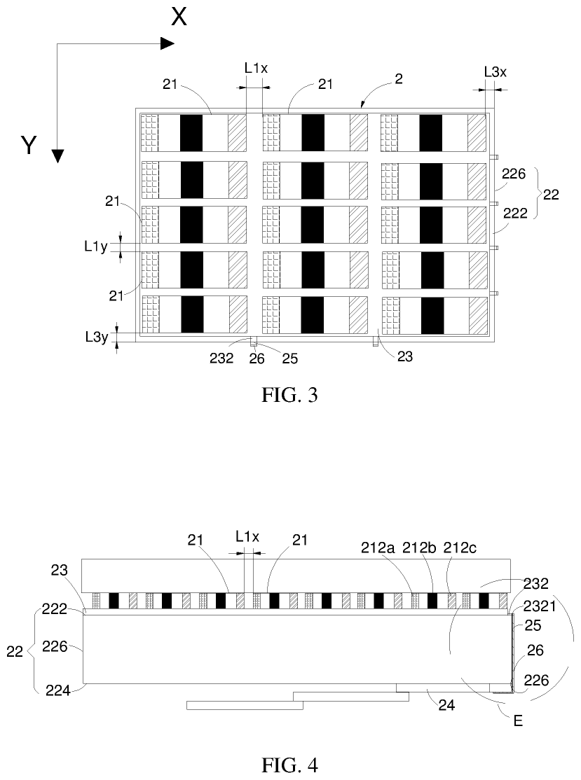

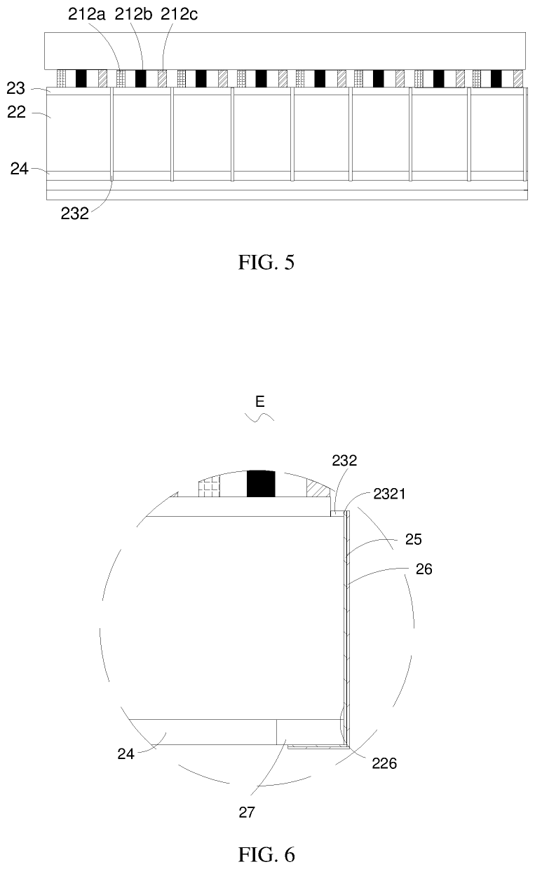

Please refer to FIG. 3, FIG. 4, FIG. 5, and FIG. 6. FIG. 3 is a top view of a display panel of an embodiment of the present disclosure. FIG. 4 is a front view of the display panel of the embodiment of the present disclosure. FIG. 5 is a left side view of the display panel of the embodiment of the present disclosure. FIG. 6 is a partial enlarged view of an E portion shown in FIG. 4.

The display panel includes a substrate 22 connected to the light-emitting units 21. The substrate 22 includes a first surface 222 provided with the light-emitting units 21 and a second surface 224 opposite to the first surface 222. A TFT drive circuit 23 is disposed between the first surface 222 of the substrate 22 and each of the light-emitting units 21. The light-emitting units 21 are electrically connected to the TFT drive circuit 23. The TFT drive circuit 23 is provided with a plurality of first leads 232. The first leads 232 extend from the TFT drive circuit 23 to a side surface 226 of the substrate 22. An external pin bonding structure 24 is disposed on the second surface 224 of the substrate 22. The side surface 226 of the display panel 2 is provided with a plurality of side conductive lines 25. One end of the side conductive line 25 is connected to the first lead 232. Another end of the side conductive line is connected to the external pin bonding structure 24.

In related technologies, the external pin bonding structure is generally directly electrically connected to the TFT drive circuit and is arranged on the same plane as the TFT drive circuit. Thus, the display panel will have the external pin bonding structure on an edge of the substrate, so a “bezel” is formed on the edge of the substrate. A size of the external pin bonding structure is much larger than the first distance. Therefore, when the external pin bonding structure is disposed on the edge of the substrate to form the “bezel,” it is difficult to achieve seamless splicing of a plurality of the display panels.

It can be understood that the TFT drive circuit 23 is disposed on the first surface 222 of the substrate 22. The external pin bonding structure 24 is disposed on the second surface 224 of the substrate 22. The first surface 222 and the second surface 224 are two opposite surfaces of the substrate 22. The side surface 226 of the substrate 22 is provided with the side conductive lines 25 to connect the external pin bonding structure 24 on the second surface 224 and the TFT drive circuit 23 on the first surface 222. In comparison with a design in the related technology where the external pin bonding structure 24 and the TFT drive circuit 23 are arranged on the same plane, a design of connecting the external pin bonding structure 24 on the second surface 224 and the TFT drive circuit 23 on the first surface 222 through the side conductive lines 25 can prevent the external pin bonding structure 24 on the edge of the substrate 22 from forming the “bezel.” This makes it possible for the ratio of the second distance to the first distance in the same splicing direction to range from 0.8 to 1.2. When the ratio of the second distance to the first distance ranges from 0.8 to 1.2, a plurality of the display panels can be seamlessly spliced at the physical and visual aspects.

The TFT drive circuit 23 generally includes the plurality of first leads 232. The first leads 232 extend from the TFT drive circuit 23 and are arranged on an edge of the TFT drive circuit 23. Each first lead 232 needs to be connected to the external pin bonding structure 24 on the second surface 224 of the substrate 22. Therefore, a number of the side conductive lines 25 is equal to a number of the first leads 232, and the side conductive lines 25 and the first leads 232 are connected in a one-to-one correspondence.

A thickness of the side conductive line 25 needs to be less than 20 micrometers.

It is understandable that the side conductive line 25 cannot have an excessive thickness. If the side conductive line is too thick, it is difficult to achieve seamless splicing between the plurality of display panels. Preferably, the thickness of the side conductive line 25 may be 10 micrometers.

The side conductive lines 25 are covered with a protective layer 26, and a thickness of the protective layer 26 is less than 20 micrometers.

It should be noted that side conductive lines 25 need to be isolated from air and moisture to function properly. Thus, it is necessary to cover the protective layer 26 on the side conductive lines 25 to ensure normal use of the side conductive lines 25 and prolong a lifespan of the side conductive lines 25. The protective layer 26 is made of an organic material and completely covers the side conductive lines 25, which has functions of preventing oxidation of the conductive lines and isolating air and moisture.

The first leads 232 extend from the TFT drive circuit 23 to the edge of the substrate 22. Also, cross-sectional surfaces 2321 of the first leads 232 are flush with the side surface 226 of the substrate 22. The side conductive lines 25 are conductively connected to the cross-sectional surfaces 2321 of the first leads 232 on the side surface 226 of the substrate 22.

It can be understood that the side conductive lines 25 are attached to the side surface 226 of the display panel 2. The first leads 232 are made of metal and extend from the TFT drive circuit 23 to the edge of the substrate 22. The cross-sectional surface 2321 of a free-end of the first lead 232 is flush with the side surface 226 of the substrate 22. A configuration of the side conductive line 25 specifically takes the cross-sectional surface 2321 of the first lead 232 as a starting point, and then it extends along the side surface 226 of the substrate 22 to the external pin bonding structure 24. At this time, the side conductive lines 25 have a “ [symbol] (mirror L-shaped)” structure.

It is understandable that the cross-sectional surface 2321 of the first lead 232 may also not be flush with the side surface 226 of the substrate 22. Correspondingly, the side conductive lines 25 may also not be set with the cross-sectional surface 2321 of the first lead 232 as the starting point. The side conductive lines 25 can cover the first leads 232, they extend from non-cross-sectional surfaces 2321 of the first lead 232 to the edge of the substrate 22, and then they are bent toward the second surface 224 at the edge of the substrate 22, and they extend along the side surface 226 to the external pin bonding structure 24. It is understandable that the side conductive lines 25 have a “ [symbol] (U-shaped)” structure at this case.

The side conductive lines 25 are conductively connected to a surface of the external pin bonding structure 24 away from the substrate 22.

It is understandable that the side conductive lines 25 are connected to the external pin bonding structure 24, which can be understood as the side conductive lines 25 completely covering the external pin bonding structure 24, which makes the connection between the side conductive lines 25 and the external pin bonding structure 24 more stable and reliable.

The display panel further includes a plurality of signal-line leads 27, and the signal-line leads 27 are configured to connect the external pin bonding structure 24 and the side conductive lines 25.

It should be noted that it is not necessary to set the signal-line leads 27 on the external pin bonding structure 24. Connecting the external pin bonding structure 24 directly to the side conductive lines 25 can also lead a signal of the TFT drive circuit 23 to the external pin bonding structure 24. The first leads 232 and the signal-line leads 27 are set to facilitate an input of the signal of the TFT drive circuit 23 into the external pin bonding structure 24.

The plurality of first leads 232 are evenly arranged on a periphery of the substrate 22 or concentratedly arranged on a same edge of the substrate 22.

It is understandable that if there are four display panels, each display panel has two edges that are not spliced with other display panels. Therefore, the first leads 232 in each display panel can be arranged on side surfaces that are not used for splicing. If there are more display panels, such as 9 display panels (arranged in 3 rows and 3 columns), four side surfaces 226 of one display panel arranged in a second row and a second column are all spliced with other display panels. At this time, the first leads 232 can be evenly arranged on a periphery of the display panel.

It should be noted that light-emitting units 21 are usually arranged by light-emitting sub-units (212a, 212b, 212c), which are usually three types of light-emitting sub-units including a R light-emitting sub-unit, a G light-emitting sub-unit, and a B light-emitting sub-unit, according to certain rules. For example, the three light-emitting sub-units can be arranged in a standard arrangement, and can also be arranged in a diamond arrangement, a delta arrangement, a yellow duck arrangement, a pentile arrangement, or other forms. It can be understood that when the three light-emitting sub-units adopt a certain arrangement, for example, when the standard arrangement is adopted, the three light-emitting sub-units can be arranged in a different order. For example, the G light-emitting sub-unit may be arranged between the R light-emitting sub-unit and the B light-emitting sub-unit, or the R light-emitting sub-unit may be arranged between the G light-emitting sub-unit and the B light-emitting sub-unit. This arrangement of the light-emitting sub-units in one light-emitting unit 21 is a first preset rule. In the same display panel, the first distance between any two adjacent light-emitting units 21 in the same splicing direction is equal, to form a periodic array of light-emitting units in the display panel. This arrangement rule between light-emitting units is a second preset rule. When each display panel is made using the first preset rule and the second preset rule at the same time, a display continuity of a single display panel can be guaranteed. At the same time, when the second distance is equal to the first distance, a periodicity of an array of the light-emitting units in the display device formed by splicing the plurality of display panels is the same as a periodicity of an array of the light-emitting units in one display panel. A periodic continuity of the light-emitting array ensures the continuity of an image, that is, a visually seamless connection.

The embodiment of the present disclosure provides the display panel, please refer to FIG. 3, FIG. 4, FIG. 5, and FIG. 6.

The display panel includes the substrate 22, the TFT drive circuit 23, the light-emitting units 21, the external pin bonding structure 24, and the plurality of side conductive lines 25.

The substrate 22 includes the first surface 222, the second surface 224 opposite to the first surface 222, and the side surface 226 connected between the first surface 222 and the second surface 224.

The TFT drive circuit 23 is disposed on the first surface 222 of the substrate 22. The TFT drive circuit 23 includes the plurality of first leads 232, and the first leads 232 extend to the side surface 226 of the substrate 22.

The light-emitting units 21 are arranged on a surface of the TFT drive circuit 23 away from the substrate 22. The light-emitting units 21 are electrically connected to the TFT drive circuit 23. Two adjacent light-emitting units 21 are separated by the first distance. The light-emitting units 21 disposed at the edge of the substrate 22 are separated from the side surface 226 by a third distance. A ratio of the third distance to the first distance in the preset direction ranges from 0.4 to 0.6.

It is understandable that the preset direction is the splicing direction. In the first splicing direction (X direction), the display panel has a first distance L1x and a third distance L3x. The third distance L3x is less than or equal to one-half of a second distance L2x. The description of the second distance is detailed above, which will not be repeated here. The ratio of the second distance L2x to the first distance L1x ranges from 0.8 to 1.2. From this, it can be calculated that a ratio of the third distance L3x to the first distance L1x ranges from 0.4 to 0.6. Similarly, in the second splicing direction (Y direction), the display panel has a first distance L1y and a third distance L3y. A ratio of the third distance L3y to the first distance L1y ranges from 0.4 to 0.6.

The external pin bonding structure 24 is disposed on the second surface 224 of the substrate 22. The plurality of side conductive lines 25 are arranged on the side surface 226 of the display panel. One end of each side conductive line 25 is connected to the corresponding first lead 232. Another end of each side conductive line 25 is connected to the external pin bonding structure 24.

The external pin bonding structure 24 includes signal-line leads 27 for connecting with the side conductive lines 25. The signal-line leads 27 are disposed close to the edge of the substrate 22. The signal-line leads 27 are connected to the plurality of side conductive lines 25 in a one-to-one correspondence.

Each side conductive line 25 is covered with a protective layer 26. An edge of the substrate 22 close to the external pin bonding structure 24 has a rounded structure.

For specific descriptions of related structures in the display panel, please refer to the descriptions of the display device 100 in this embodiment, which will not be repeated here.

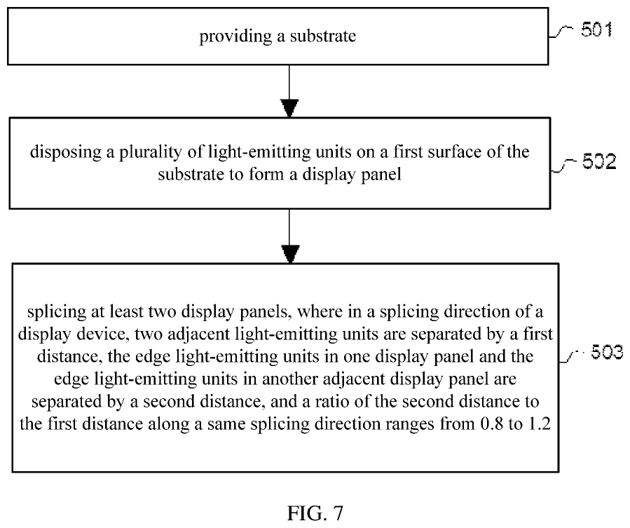

Please refer to FIG. 7 for a display device. FIG. 7 is a flowchart of a manufacturing method of a display device of an embodiment of the present disclosure, including following steps.

In a step 501, a substrate is provided.

It should be noted that the substrate is configured to support other structures.

In a step 502, a plurality of light-emitting units are disposed on a first surface of the substrate to form a display panel.

It should be noted that the light-emitting units are all composed of R light-emitting sub-unit, G light-emitting sub-unit, and B light-emitting sub-unit. The light-emitting units are disposed on the substrate, specifically, the R light-emitting sub-units, the G light-emitting sub-units, and the B light-emitting sub-units are disposed on the substrate according to a certain rule, so that each light-emitting sub-unit forms a light-emitting unit array with periodic distance. It is understandable that after completing the arrangement of the light-emitting units, it is necessary to perform a lighting test on the light-emitting units to detect a mass transfer yield, thereby repairing pixel defects.

In a step 503, at least two display panels are spliced. In a splicing direction of the display device, two adjacent light-emitting units are separated by a first distance. The edge light-emitting units in one display panel and the edge light-emitting units in another adjacent display panel are separated by a second distance. A ratio of the second distance to the first distance along a same splicing direction ranges from 0.8 to 1.2.

The second distance is related to a distance between two adjacent display panels in the splicing direction. If the second distance is too large, the distance between two adjacent display panels is too far, and there will be a gap between the two display panels visually, which will affect a continuity of an image. In related technologies, the second distance being much larger than the first distance is a main reason for discontinuity of an image. In the display device of the embodiment of the present disclosure, the ratio of the second distance to the first distance along the same splicing direction ranges from 0.8 to 1.2, so that the gap between two adjacent display panels at a splicing point is in a reasonable range. It prevents visually seeing a gap between two adjacent display panels. It should be noted that the ratio of the second distance to the first distance is set based on experimental experience and human vision research.

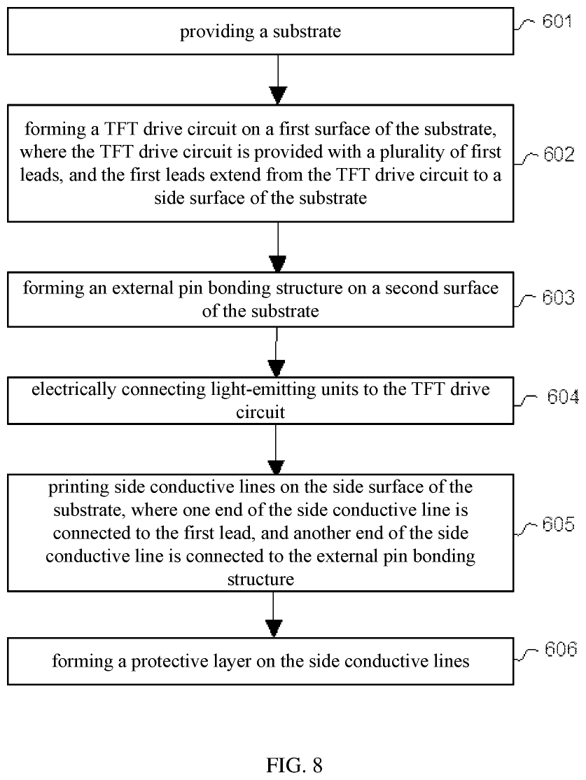

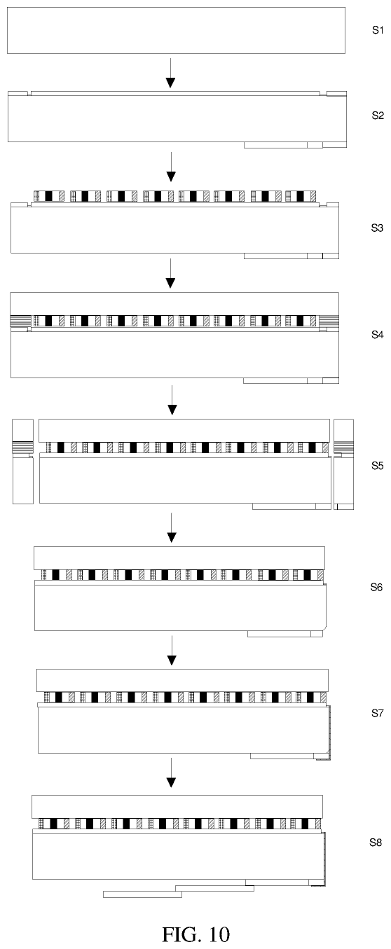

Please refer to FIG. 8 and FIG. 10. FIG. 8 is a first flowchart of a manufacturing method of a display panel of an embodiment of the present disclosure. FIG. 10 shows schematic diagrams of manufacturing processes of the display panel of the embodiment of the present disclosure. The manufacturing method of the display panel can include following steps.

In a step 601, a substrate is provided.

In a step 602, a TFT drive circuit is formed on a first surface of the substrate. The TFT drive circuit is provided with a plurality of first leads, and the first leads extend from the TFT drive circuit to a side surface of the substrate.

It is understandable that the first leads extend to an edge of the substrate so that cross-sectional surfaces of the first leads are flush with the side surface of the substrate. The cross-sectional surfaces of the first leads may also not be flush with the side surface of the substrate.

In a step 603, an external pin bonding structure is formed on a second surface of the substrate.

It can be understood that in the embodiment of the present disclosure, the external pin bonding structure and the TFT drive circuit are arranged on different planes. Specifically, they are disposed on two opposite surfaces of the substrate, and can be attached through external pins to prevent forming a “bezel” structure on the side surface of the substrate. For details of the step 602 and the step 603, refer to a step S1 in FIG. 10.

In a step 604, Light-emitting units are electrically connected to the TFT drive circuit.

In a step 605, side conductive lines are printed on the side surface of the substrate. One end of the side conductive line is connected to the first lead. Another end of the side conductive line is connected to the external pin bonding structure.

It should be noted that in an actual test, it is found that if the side conductive lines are formed first and then the light-emitting units are connected to the TFT drive circuit, it will increase a difficulty of a lighting test. Therefore, in the display panel of the present disclosure, the light-emitting units is first connected to the TFT drive circuit, and then the side conductive lines are formed.

In a step 606, a protective layer is formed on the side conductive lines.

The step 605 and the step 606 are a step S7 in FIG. 10.

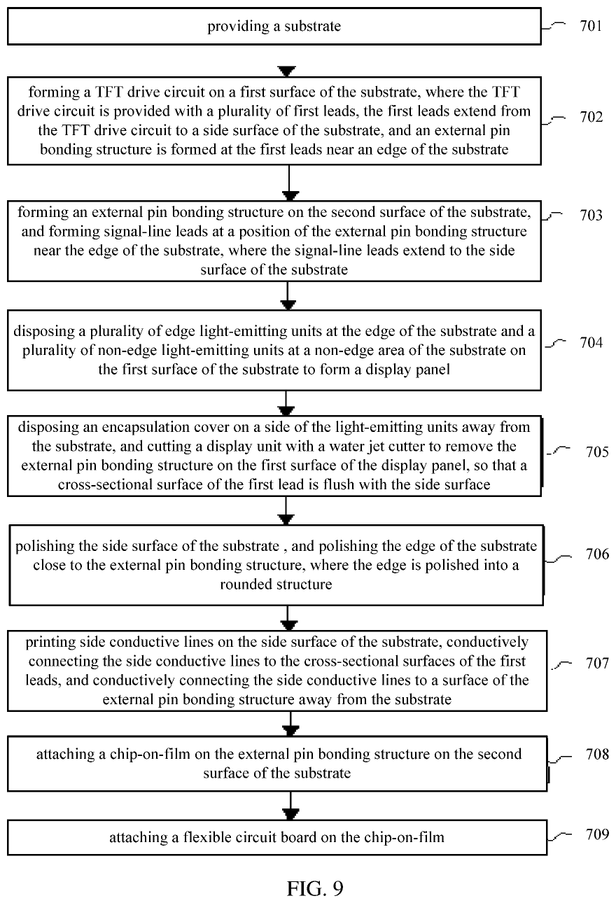

Please refer to FIG. 9 and FIG. 10. FIG. 9 is a second flowchart of a manufacturing method of a display panel of an embodiment of the present disclosure. The manufacturing method of display panel may further include following steps.

In a step 701, a substrate is provided.

In a step 702, a TFT drive circuit is formed on a first surface of the substrate. The TFT drive circuit is provided with a plurality of first leads, and the first leads extend from the TFT drive circuit to a side surface of the substrate. Also, an external pin bonding structure is formed at the first leads near an edge of the substrate.

It should be noted that a formation of the external pin bonding structure on the first surface of substrate is a very mature existing technology in this field.

In a step 703, an external pin bonding structure is formed on the second surface of the substrate. Signal-line leads are formed at a position of the external pin bonding structure near the edge of the substrate. The signal-line leads extend to the side surface of the substrate.

In a step 704, a plurality of edge light-emitting units at the edge of the substrate and a plurality of non-edge light-emitting units at a non-edge area of the substrate are disposed on the first surface of the substrate to form a display panel.

In a step 705, an encapsulation cover is disposed on a side of the light-emitting units away from the substrate. A display unit is cut with a water jet cutter to remove the external pin bonding structure on the first surface of the display panel, so that a cross-sectional surface of the first lead is flush with the side surface.

Specifically, please refer to a step S4 and a step S5 in FIG. 10. It is understandable that a purpose of setting the encapsulation cover is to prevent light-emitting sub-units from peeling off, and to prevent the light-emitting sub-units from being corroded by water and oxygen and failing. The encapsulation cover can be a glass substrate or a cover made of organic materials. A thickness of the encapsulation cover ranges from 1 to 20 um, and a light transmittance is greater than 95%. For example, the encapsulation cover may be made of silica gel or an acrylic material. The encapsulation cover is used with an encapsulation adhesive. Specifically, a dam adhesive and a fill adhesive can be used to align and adhere the cover on the light-emitting units.

It should be noted that after the encapsulation step is completed, a formation of the display panel is initially completed. However, in the step 702, the external pin bonding structure is disposed on the first surface of the substrate. At this time, the display panel has a “bezel”. This is a display panel manufactured by a common production technology in this field. Furthermore, in the step 705, the display panel manufactured by the prior art is cut, and the “bezel” formed by the external pin bonding structure in the display panel can be removed. This improvement does not require new processing equipment, which is conducive to cost savings.

In a step 706, the side surface of the substrate is polished. The edge of the substrate close to the external pin bonding structure is polished, and the edge is polished into a rounded structure.

Specifically, please refer to a step S6 in FIG. 10.

In a step 707, side conductive lines are printed on the side surface of the substrate. The side conductive lines are conductively connected to cross-sectional surfaces of the first leads, and the side conductive lines are conductively connected to a surface of the external pin bonding structure away from the substrate.

It is understandable that although the external pin bonding structure on the first surface of the substrate is cut off, a signal on the first surface can still be transmitted into the external pin bonding structure on the second surface through the side conductive lines, the first leads, and the signal-line leads. A combination of these three makes it possible to set the external pin bonding structure only on the second surface of the substrate.

In a step 708, a chip-on-film is attached on the external pin bonding structure on the second surface of the substrate.

In a step 709, a flexible circuit board is attached on the chip-on-film.

Specifically, for the step 708 and the step 709, please refer to a step S8 in FIG. 10.

It can be understood that the flexible circuit board is connected to a driving system, so that the display can be driven.

In the foregoing embodiments, the description of each embodiment has its own focus. For a part that is not described in detail in one embodiment, reference may be made to related descriptions of other embodiments.

The display device and the display panel of the embodiments of the present disclosure are described in detail above. Specific embodiments are used in this specification to illustrate principles and implementations of the present disclosure. The description of the above embodiments is only used to help understand methods and core ideas of the present disclosure. For those skilled in the art, based on the ideas of the present disclosure, there will be changes in the specific implementations and a scope of the application. In summary, contents of this specification should not be construed as a restriction on the present disclosure.

What is claimed is:

1. A display device, comprising: a plurality of display panels configured to be spliced to form the display device, wherein each of the display panels comprises a plurality of light-emitting units;
in a splicing direction of the display panels, two adjacent light-emitting units in each of the display panels are separated by a first distance;
the plurality of light-emitting units comprise a plurality of edge light-emitting units adjacent to another display panel along the splicing direction;
the edge light-emitting units in one of the display panels are separated from the edge light-emitting units in another adjacent display panel by a second distance; and
a ratio of the second distance to the first distance in the splicing direction ranges from 0.8 to 1.2.

2. The display device according to claim 1, wherein the ratio of the second distance to the first distance in the splicing direction is 1.

3. The display device according to claim 1, wherein each of the display panels further comprises:
a substrate, wherein the substrate comprises a first surface, a second surface opposite to the first surface, and a side surface connected between the first surface and the second surface, and the light-emitting units are disposed on the first surface;
a thin film transistor (TFT) drive circuit disposed between the first surface and the light-emitting units, wherein the TFT drive circuit is electrically connected to the light-emitting units, the TFT drive circuit comprises a plurality of first leads, and each of the first leads extends from the light-emitting units to the side surface of the substrate;
an external pin bonding structure disposed on the second surface of the substrate; and
a plurality of side conductive lines disposed on the side surface, wherein one end of each of the side conductive lines is connected to a corresponding first lead, and another end of each of the side conductive lines is connected to the external pin bonding structure.

4. The display device according to claim 3, further comprising a protective layer covering the side conductive lines.

5. The display device according to claim 3, wherein a cross-sectional surface of the first lead is flush with the side surface of the substrate, and the side conductive line is conductively connected to the cross-sectional surface of the first lead on the side surface.

6. The display device according to claim 3, wherein the side conductive line is conductively connected to a surface of the external pin bonding structure away from the substrate; and/or
the side conductive line is conductively connected to a surface of the first lead away from the substrate.

7. The display device according to claim 3, wherein the plurality of the side conductive lines are evenly arranged on the side surface of the substrate or concentratedly arranged on a same side surface of the substrate.

8. The display device according to claim 3, wherein each of the display panels further comprises a plurality of signal-line leads, and the signal-line leads are configured to connect the external pin bonding structure and the side conductive lines.

9. A display panel, comprising:
a substrate comprising a first surface, a second surface opposite to the first surface, and a side surface connected between the first surface and the second surface; and
a plurality of light-emitting units disposed on the first surface of the substrate, wherein in a preset direction, two adjacent light-emitting units are separated by a first distance, the light-emitting units arranged at an edge of the substrate are separated from the side surface by a third distance, and a ratio of the third distance to the first distance in the preset direction ranges from 0.4 to 0.6.

10. The display panel according to claim 9, further comprising:
a thin film transistor (TFT) drive circuit disposed on the first surface of the substrate, wherein the light-emitting units are disposed on a surface of the TFT drive circuit away from the substrate, the TFT drive circuit comprises a plurality of first leads, and each of the first leads extends toward the side surface of the substrate;
an external pin bonding structure disposed on the second surface of the substrate; and
a plurality of side conductive lines disposed on the side surface of the display panel, wherein one end of each of the side conductive lines is connected to a corresponding first lead, and another end of each of the side conductive lines is connected to the external pin bonding structure.

11. The display panel according to claim 10, wherein the external pin bonding structure comprises a plurality of signal-line leads configured to connect with the side conductive lines, the signal-line leads are arranged close to the edge of the substrate, and the signal-line leads are connected to plurality of side conductive lines in a one-to-one correspondence.

12. The display panel according to claim 10, further comprising a protective layer covering the side conductive lines.

13. The display panel according to claim 10, wherein a cross-sectional surface of the first lead is flush with the side surface of the substrate, and the side conductive line is conductively connected to the cross-sectional surface of the first lead on the side surface.

14. The display panel according to claim 10, wherein the side conductive line is conductively connected to a surface of the external pin bonding structure away from the substrate; and/or
the side conductive line is conductively connected to a surface of the first lead away from the substrate.

15. The display panel according to claim 10, wherein the plurality of the side conductive lines are evenly arranged on the side surface of the substrate or concentratedly arranged on a same side surface of the substrate.

16. The display panel according to claim 10, further comprising a plurality of signal-line leads, wherein the signal-line leads are configured to connect the external pin bonding structure and the side conductive lines.

17. A display device, comprising: a plurality of display panels configured to be spliced to form the display device, wherein each of the display panels comprises a plurality of light-emitting units;
in a splicing direction of the display panels, two adjacent light-emitting units in each of the display panels are separated by a first distance;
the plurality of light-emitting units comprise a plurality of edge light-emitting units adjacent to another display panel along the splicing direction;
the edge light-emitting units in one of the display panels are separated from the edge light-emitting units in another adjacent display panel by a second distance;
in the splicing direction of the display panels, a sum of a length of the light-emitting units and the first distance is a fourth distance;
a sum of a length of the edge light-emitting units and the second distance is a fifth distance; and
a ratio of the fifth distance to the fourth distance in the splicing direction ranges from 0.9 to 1.1.

18. The display device according to claim 17, wherein the display panels further comprise:
a substrate, wherein the substrate comprises a first surface, a second surface opposite to the first surface, and a side surface connected between the first surface and the second surface, and the light-emitting units are disposed on the first surface;
a thin film transistor (TFT) drive circuit disposed between the first surface and the light-emitting units, wherein the TFT drive circuit is electrically connected to the light-emitting units, the TFT drive circuit comprises a plurality of first leads, and each of the first leads extends from the light-emitting units to the side surface of the substrate;
an external pin bonding structure disposed on the second surface of the substrate; and
a plurality of side conductive lines disposed on the side surface, wherein one end of each of the side conductive lines is connected to a corresponding first lead, and another end of each of the side conductive lines is connected to the external pin bonding structure.

19. The display device according to claim 18, further comprising a protective layer covering the side conductive lines.

20. The display device according to claim 17, wherein the display panels are rectangular.
